(19) United States
(12) Patent Application Publication
(10) Pub. No.: US 2022/0081768 A1
(43) Pub. Date: Mar. 17, 2022

(54) PROCESSING APPARATUS

(71) Applicant: Tokyo Electron Limited, Tokyo (JP)

(72) Inventor: Hiroki IRIUDA, Yamanashi (JP)

(21) Appl. No.: 17/472,945

(22) Filed: Sep. 13, 2021

(30) Foreign Application Priority Data
Sep. 17, 2020 (JP) 2020-156409

(51) Int. Cl. C23C 16/455; C23C 16/458; C23C 16/40

(52) U.S. Cl. CPC C23C 16/45525; C23C 16/45563; H01L 21/02164; C23C 16/401; C23C 16/4583

(57) ABSTRACT

A processing apparatus includes a processing container that has substantially a cylindrical shape and accommodates a plurality of substrates in multiple tiers at intervals in the longitudinal direction of the processing container; and a gas nozzle that extends in the longitudinal direction of the processing container and has a plurality of gas holes provided at intervals in a longitudinal direction of the gas nozzle to eject a gas into the processing container. The gas holes are arranged every other tier of the plurality of substrates accommodated in multiple tiers, and the gas holes eject the gas toward the side surfaces of the corresponding substrates.

### CROSS-REFERENCE TO RELATED APPLICATIONS

This application is based on and claims priority from Japanese Patent Application No. 2020-156409, filed on Sep. 17, 2020 with the Japan Patent Office, the disclosure of which is incorporated herein in its entirety by reference.

### TECHNICAL FIELD

The present disclosure relates to a processing apparatus.

### BACKGROUND

There is a film forming apparatus including a gas dispersion nozzle extending in the vertical direction along the inside of the side wall of a cylindrical shape processing container and having a plurality of gas ejection holes formed over a length in the vertical direction corresponding to a wafer support range of a wafer boat (see, e.g., Japanese Patent Laid-Open Publication No. 2011-135044).

### SUMMARY

A processing apparatus according to an embodiment of the present disclosure includes a processing container having a substantially cylindrical shape and configured to accommodate a plurality of substrates in multiple tiers at intervals in a longitudinal direction of the processing container; and a gas nozzle extending in the longitudinal direction of the processing container and having a plurality of gas holes provided at intervals in the longitudinal direction of the gas nozzle to eject a gas in the processing container. The plurality of gas holes are arranged every other tier of the plurality of substrates accommodated in multiple tiers, and the plurality of gas holes eject the gas toward side surfaces of corresponding substrates.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic view illustrating a processing apparatus according to an embodiment.

FIG. 2 is a schematic view illustrating an example of arrangement of gas nozzles.

FIG. 3 is a view illustrating an example of the positional relationship between gas holes and wafers.

FIG. 4 is a diagram for explaining simulation conditions.

FIG. 5 is a diagram illustrating analysis results of the flow velocity distribution of a gas of the in-plane of a wafer.

FIGS. 6A to 6C are diagrams illustrating analysis results of the flow velocity distribution of a gas of the in-plane of a wafer.

FIG. 7 is a diagram illustrating analysis results of the flow velocity distribution of a gas of the in-plane of a wafer.

FIGS. 8A to 8C are diagrams illustrating analysis results of the flow velocity distribution of a gas between wafers.

FIGS. 9A and 9B are diagrams illustrating analysis results of the active species concentration distribution between wafers.

FIG. 10 is a view illustrating another example of the positional relationship between gas holes and wafers.

### DESCRIPTION OF EMBODIMENT

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, non-limiting exemplary embodiments of the present disclosure will be described with reference to the accompanying drawings. In all of the accompanying drawings, the same or corresponding members or parts are denoted by the same or corresponding reference numerals, and redundant explanations are omitted.

[Processing Apparatus]

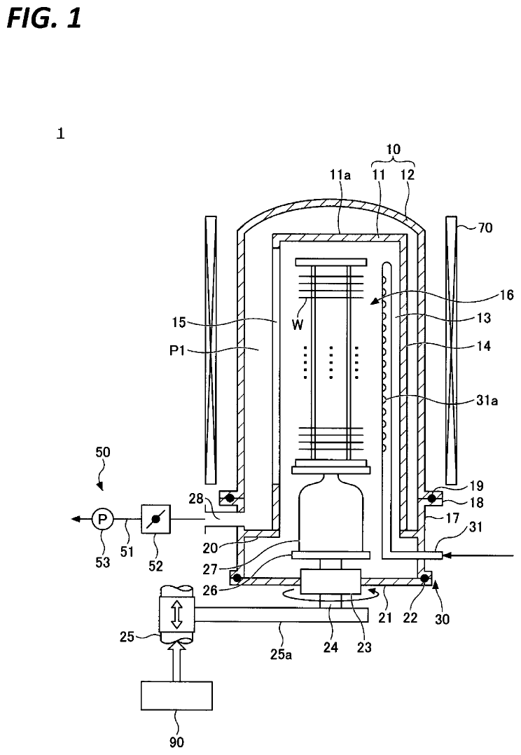

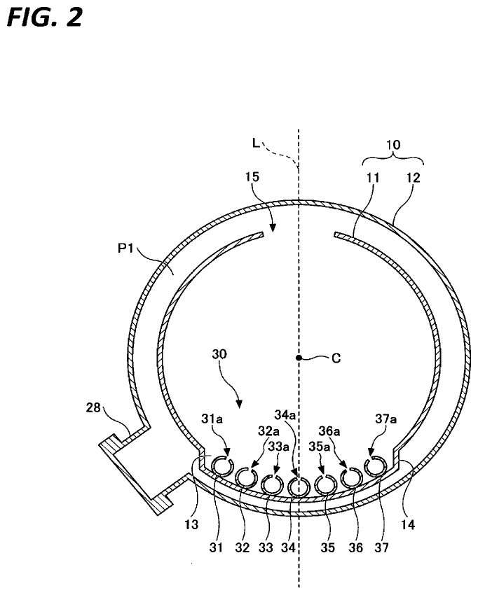

An example of a processing apparatus according to an embodiment will be described with reference to FIGS. 1 and 2. FIG. 1 is a schematic view illustrating an example of the processing apparatus according to the embodiment. FIG. 2 is a schematic view illustrating an example of arrangement of gas nozzles.

The processing apparatus 1 includes a processing container 10, a gas supply 30, an exhauster 50, a heater 70, and a controller 90.

The processing container 10 includes an inner tube 11 and an outer tube 12. The inner tube 11 is formed in substantially a cylindrical shape with a ceiling having its lower end opened. The inner tube 11 has a ceiling portion 11a formed in, for example, a flat shape. The outer tube 12 is formed in substantially a cylindrical shape with a ceiling having its lower end opened and covering the outside of the inner tube 11. The inner tube 11 and the outer tube 12 are arranged coaxially to form a double-tube structure. The inner tube 11 and the outer tube 12 are made of a heat-resistant material such as quartz.

On one side of the inner tube 11, an accommodation portion 13 is formed along its longitudinal direction (vertical direction) to accommodate gas nozzles. In the accommodation portion 13, a portion of the side wall of the inner tube 11 is projected outward to form a convex portion 14 with the inside thereof formed as the accommodation portion 13.

A rectangular exhaust slit 15 is formed along its longitudinal direction (vertical direction) on the side wall on the opposite side of the inner tube 11 which faces the accommodation portion 13. The exhaust slit 15 exhausts a gas in the inner tube 11. The length of the exhaust slit 15 is the same as the length of a boat 16 to be described later, or is formed so as to extend in the vertical direction longer than the length of the boat 16.

The processing container 10 accommodates the boat 16. The boat 16 holds a plurality of substrates substantially horizontally at intervals in the vertical direction. The substrate may be, for example, a semiconductor wafer (hereinafter referred to as a “wafer W”).

The lower end of the processing container 10 is supported by substantially a cylindrical manifold 17 made of, for example, stainless steel. A flange 18 is formed at the upper end of the manifold 17, and the lower end of the outer tube 12 is provided on and supported by the flange 18. A sealing member 19 such as an O-ring is interposed between the flange 18 and the lower end of the outer tube 12 to keep the inside of the outer tube 12 in an airtight state.

An annular support 20 is provided on the inner wall of the upper portion of the manifold 17. The support 20 supports the lower end of the inner tube 11. A cover 21 is air-tightly attached to the opening at the lower end of the manifold 17 via a sealing member 22 such as an O-ring. The cover 21 air-tightly closes the opening at the lower end of the processing container 10, that is, the opening of the manifold 17. The cover 21 is made of, for example, stainless steel.

A rotating shaft 24 is provided through the center of the cover 21 to rotatably support the boat 16 via a magnetic fluid seal 23. The lower portion of the rotating shaft 24 is rotatably supported by an arm 25a of an elevating mechanism 25 including a boat elevator.

A rotating plate 26 is provided at the upper end of the rotating shaft 24. The boat 16 is placed on the rotating plate 26 to hold the wafer W via a thermal insulator 27 made of quartz. Therefore, by raising and lowering the elevating mechanism 25, the cover 21 and the boat 16 move up and down as a one body, so that the boat 16 is able to be inserted and removed from the inside of the processing container 10.

The gas supply 30 is provided on the manifold 17. The gas supply 30 has a plurality of (e.g., seven) gas nozzles 31 to 37.

The plurality of gas nozzles 31 to 37 are arranged in a row in the accommodation portion 13 of the inner tube 11 along the circumferential direction. Each of the gas nozzles 31 to 37 is provided in the inner tube 11 along its longitudinal direction and is supported so that its base end is bent in an L shape and penetrates the manifold 17. Each of the gas nozzles 31 to 37 is formed with a plurality of gas holes 31a to 37a at predetermined intervals along its longitudinal direction. The plurality of gas holes 31a to 37a are oriented toward, for example, a center C of the inner tube 11 (wafer W side).

The gas nozzles 31 to 37 eject various gases, for example, a precursor gas, a reaction gas, an etching gas, and a purge gas, substantially horizontally from the plurality of gas holes 31a to 37a toward the wafer W. The precursor gas may be, for example, a gas containing silicon (Si) or metal. The reaction gas is a gas for reacting with the precursor gas to produce a reaction product and may be, for example, a gas containing oxygen or nitrogen. The etching gas is a gas for etching various films and may be, for example, a gas containing halogen such as fluorine, chlorine, or bromine. The purge gas is a gas for purging the precursor gas or the reaction gas remaining in the processing container 10 and may be, for example, an inert gas. The details of the gas nozzles 31 to 37 will be described later.

The exhauster 50 exhausts a gas ejected from the inner tube 11 through the exhaust slit 15 and ejected from a gas outlet 28 through a space P1 between the inner tube 11 and the outer tube 12. The gas outlet 28 is the upper side wall of the manifold 17 and is formed above the support 20. An exhaust passage 51 is connected to the gas outlet 28. A pressure adjusting valve 52 and a vacuum pump 53 are sequentially provided in the exhaust passage 51 so that the inside of the processing container 10 may be exhausted.

The heater 70 is provided around the outer tube 12. The heater 70 is provided on, for example, a base plate (not illustrated). The heater 70 has substantially a cylindrical shape so as to cover the outer tube 12. The heater 70 includes, for example, a heating element and heats the wafer W in the processing container 10.

The controller 90 controls the operation of each unit of the processing apparatus 1. The controller 90 may be, for example, a computer. A computer program that operates each part of the processing apparatus 1 is stored in a storage medium. The storage medium may be, for example, a flexible disk, a compact disc, a hard disk, a flash memory, or a DVD.

[Gas Nozzle]

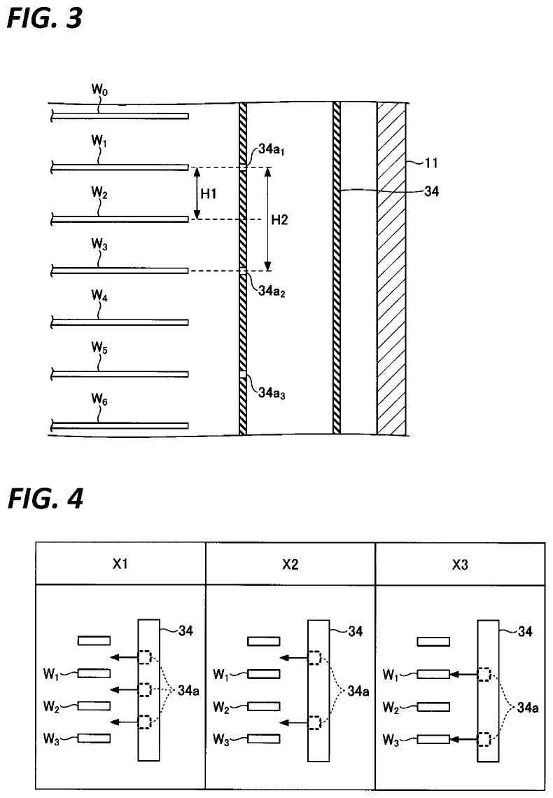

An example of the positional relationship between gas holes of a gas nozzle and wafers will be described with reference to FIG. 3. Hereinafter, the gas nozzle 34 will be described as an example, but other gas nozzles 31 to 33 and 35 to 37 may have the same configuration as the gas nozzle 34.

As illustrated in FIG. 3, the gas nozzle 34 extends in the longitudinal direction of the inner tube 11. The gas nozzle 34 is formed with a plurality of gas holes 34a₁ to 34aₙ at predetermined intervals along the longitudinal direction thereof. Here, n is aₙ integer of 1 or more. The plurality of gas holes 34a₁ to 34aₙ are oriented toward, for example, the center C of the inner tube 11 (wafer W side). The plurality of gas holes 34a₁ to 34aₙ are arranged every other tier of a plurality of wafers W₁ to Wₙ accommodated in multiple tiers in the inner tube 11 and eject a gas toward the side surfaces of the corresponding wafers W1 to Wₙ. In this way, the plurality of gas holes 34a₁ to 34aₙ are arranged so that the pitch H2 between the adjacent gas holes 34a is twice the pitch H1 between the adjacent wafers W and eject a gas toward on the side surfaces of the corresponding wafers W₁ to Wₙ.

Specifically, the gas hole 34a₁ is disposed at the same height as the wafer W₁ and faces the side surface of the wafer W₁. As a result, the gas hole 34a₁ ejects a gas toward the side surface of the wafer W₁. The gas ejected from the gas hole 34a₁ collides with the side surface of the wafer W₁ to become a flow which is separated between the wafer W₀ and the wafer W₁ and between the wafer W₁ and the wafer W₂. That is, substantially the same flow rate of the gas is supplied to the upper surface of the wafer W₁ and the upper surface of the wafer W₂.

Further, the gas hole 34a₂ is disposed at the same height as the wafer W₃ and faces the side surface of the wafer W₃. As a result, the gas hole 34a₂ ejects a gas toward the side surface of the wafer W₃. The gas ejected from the gas hole 34a₂ collides with the side surface of the wafer W₃ to become a flow which is separated between the wafer W₂ and the wafer W₃ and between the wafer W₃ and the wafer W₄. That is, substantially the same flow rate of the gas is supplied to the upper surface of the wafer W₃ and the upper surface of the wafer W₄.

Further, the gas hole 34a₃ is disposed at the same height as the wafer W₅ and faces the side surface of the wafer W₅. As a result, the gas hole 34a₃ ejects a gas toward the side surface of the wafer W₅. The gas ejected from the gas hole 34a₃ collides with the side surface of the wafer W₅ to become a flow which is separated between the wafer W₄ and the wafer W₅ and between the wafer W₅ and the wafer W₆. That is, substantially the same flow rate of the gas is supplied to the upper surface of the wafer W₅ and the upper surface of the wafer W₆.

Similarly, the gas hole 34aₙ is disposed at the same height as the wafer W₂ₙ₋₁ and faces the side surface of the wafer W₂ₙ₋₁. As a result, the gas hole 34aₙ ejects a gas toward the side surface of the wafer W₂ₙ₋₁. The gas ejected from the gas hole 34aₙ collides with the side surface of the wafer W₂ₙ₋₁ to become a flow which is separated between the wafer W₂ₙ₋₂ and the wafer W₂ₙ₋₁ and between the wafer W₂ₙ₋₁ and the wafer W₂ₙ. That is, substantially the same flow rate of the gas is supplied to the upper surface of the wafer W₂ₙ₋₁ and the upper surface of the wafer W₂ₙ.

As described above, the gas ejected from the gas holes 34a₁ to 34aₙ hits the side surfaces of the wafers W₁ to Wₙ to become the flow which is separated between the upper and lower wafers W. Therefore, even when the gas holes 34a₁ to 34aₙ are arranged so that the pitch H2 between the adjacent gas holes 34a is twice the pitch H1 between the adjacent wafers W, the gas is evenly supplied to all the wafers W₁ to Wₙ. As a result, the variation in processing between the wafers W₁ and Wₙ can be reduced, thereby improving the inter-plane uniformity. Further, since the number of gas holes is halved as compared with a case where the gas holes are formed corresponding to the plurality of wafers W₁ to Wₙ, the flow velocity of the gas ejected from each gas hole can be increased. Therefore, the gas flow velocity in the central portion of the wafer can be increased. As a result, the variation in the gas flow velocity between the center portion of the wafer and the end portion of the wafer can be reduced, thereby improving the in-plane uniformity of the processing.

[Processing Method]

As an example of a processing method according to an embodiment, a method of forming a silicon oxide film on a wafer W by an atomic layer deposition (ALD) method using the processing apparatus 1 illustrated in FIGS. 1 and 2 will be described. The processing apparatus 1 will be described as having the same configuration as the gas nozzle 34 illustrated in FIG. 3 for the gas nozzles 31 to 33 and 35 to 37.

First, the controller 90 controls the elevating mechanism 25 to load the boat 16 holding a plurality of wafers W into the processing container 10, and air-tightly closes and seal the opening at the lower end of the processing container 10 by the cover 21.

Subsequently, the controller 90 repeats a cycle including step S1 of supplying a precursor gas, step S2 of purging, step S3 of supplying a reaction gas, and step S4 of purging a predetermined number of times, thereby forming a silicon oxide film having a desired film thickness on each of the plurality of wafers W.

In step S1, by ejecting a silicon-containing gas, which is the precursor gas, into the processing container 10 from at least one of the seven gas nozzles 31 to 37, the silicon-containing gas is adsorbed on the plurality of wafers W.

In step S2, the silicon-containing gas remaining in the processing container 10 are ejected by cycle purging that repeats gas replacement and evacuation. The gas replacement is an operation of supplying a purge gas into the processing container 10 from at least one of the seven gas nozzles 31 to 37. The evacuation is an operation of exhausting the inside of the processing container 10 by the vacuum pump 53.

In step S3, by ejecting an oxidizing gas, which is the reaction gas, into the processing container 10 from at least one of the seven gas nozzles 31 to 37, the silicon precursor gas adsorbed on the plurality of wafers W is oxidized by the oxidizing gas.

In step S4, the oxidizing gas remaining in the processing container 10 are ejected by cycle purging that repeats gas replacement and evacuation. Step S4 may be the same as step S2.

After repeating an ALD cycle including steps S1 to S4 a predetermined number of times, the controller 90 controls the elevating mechanism 25 to unload the boat 16 from the processing container 10.

As another example of the processing method according to the embodiment, a method of forming a silicon film on a wafer W by a chemical vapor deposition (CVD) method using the processing apparatus 1 illustrated in FIGS. 1 and 2 will be described.

First, the controller 90 controls the elevating mechanism 25 to load the boat 16 holding a plurality of wafers W into the processing container 10, and air-tightly closes and seal the opening at the lower end of the processing container 10 by the cover 21.

Subsequently, by ejecting a silicon-containing gas, which is the precursor gas, into the processing container 10 from at least one of the seven gas nozzles 31 to 37, a silicon film having a desired film thickness is formed on the wafer W.

Subsequently, the controller 90 controls the elevating mechanism 25 to unload the boat 16 from the processing container 10.

According to the above-described embodiment, when the precursor gas or the reaction gas is ejected into the inner tube 11, the gas is ejected from the plurality of gas holes 31a to 37a arranged every other tiers of the wafers W₁ to Wₙ accommodated in multiple tiers in the inner tube 11 toward the side surfaces of the corresponding wafers W₁ to Wₙ As a result, the gas ejected from the gas holes 31a to 37a hits the side surfaces of the wafers W₁ to Wₙ to become a flow which is separated between the upper and lower wafers W. Therefore, even when the gas holes 34a₁ to 34aₙ are arranged so that the pitch H2 between the adjacent gas holes 34a is twice the pitch H1 between the adjacent wafers W, the gas is evenly supplied to all the wafers W₁ to Wₙ As a result, the variation in processing between the wafers W₁ and Wₙ may be reduced, thereby improving the inter-plane uniformity. Further, since the number of gas holes is halved as compared with a case where the gas holes are formed corresponding to the plurality of wafers W₁ to Wₙ, the flow velocity of the gas ejected from each gas hole can be increased. Therefore, the gas flow velocity in the central portion of the wafer can be increased. As a result, the variation in the gas flow velocity between the center portion of the wafer and the end portion of the wafer can be reduced, thereby improving the in-plane uniformity of the processing.

[Simulation Results]

First, in the processing apparatus 1 illustrated in FIGS. 1 and 2, a simulation by thermo-fluid analysis is conducted on the flow velocity distribution on the wafer W of a gas ejected from the gas holes 34a of the gas nozzle 34 into the inner tube 11. In this simulation, three levels X1 to X3 in which the arrangement of the gas holes 34a is changed are analyzed.

FIG. 4 is a diagram for explaining simulation conditions. FIG. 4 illustrates the arrangement of the gas holes 34a at level X1, level X2, and level X3 in order from the left side.

Level X1 is a condition in which the number of gas holes 34a is equal to the number of wafers W and each of the gas holes 34a is arranged at an intermediate position between adjacent wafers W in the vertical direction.

Level X2 is a condition in which the number of gas holes 34a is thinned out to half the number of wafers W and each of the gas holes 34a is arranged at an intermediate position between adjacent wafers W in the vertical direction.

Level X3 is a condition in which the number of gas holes 34a is thinned out to half the number of wafers W and each of the gas holes 34a is arranged at the same height as the wafer W.

FIG. 5 is a diagram illustrating analysis results of the flow velocity distribution of a gas of the in-plane of a wafer. This figure illustrates the in-plane distribution of the flow velocity of a gas on three wafers W₁ to W₃ continuously arranged in the height direction illustrated in FIG. 4 for each of levels X1 to X3. In each in-plane distribution, the 6 o'clock direction indicates a direction in which the gas nozzle 34 is arranged, and the 12 o'clock direction indicates a direction in which the exhaust slit 15 is arranged.

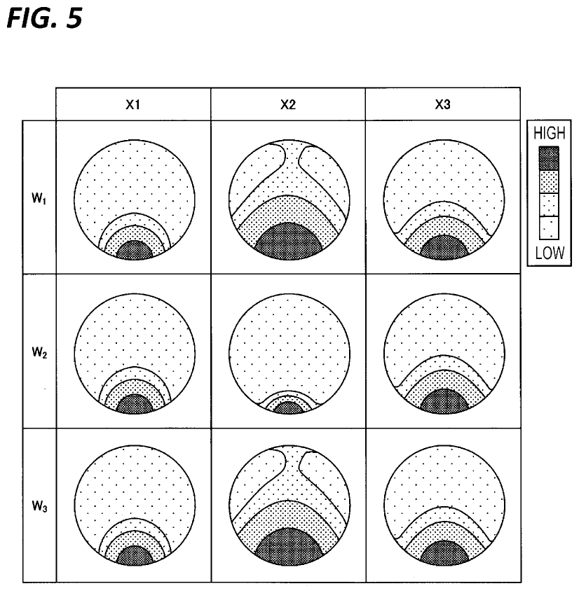

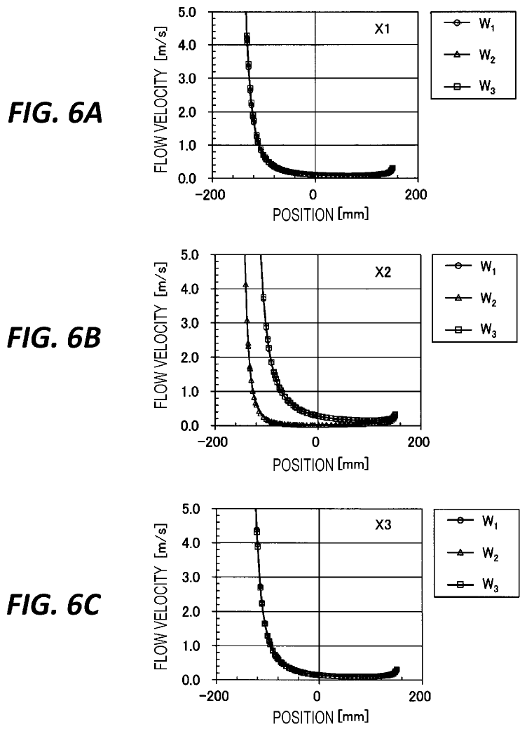

FIGS. 6A to 6C are diagrams illustrating analysis results of the flow velocity distribution of a gas of the in-plane of a wafer. This figure illustrates the flow velocity of a gas on a straight line from the 6 o'clock direction to the 12 o'clock direction of the in-plane distribution in FIG. 5. In FIGS. 6A to 6C, the horizontal axis represents the position [mm] and the vertical axis represents the gas flow velocity [m/s]. As for the position, −150 mm is the outer end of the wafer W in the 6 o'clock direction, 0 mm is the center of the wafer W, and +150 mm is the outer end of the wafer W in the 12 o'clock direction. FIG. 6A illustrates the result of level X1, FIG. 6B illustrates the result of level X2, and FIG. 6C illustrates the result of level X3.

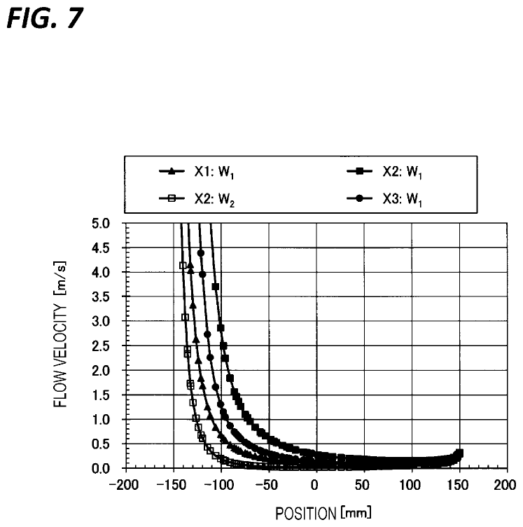

FIG. 7 is a diagram illustrating analysis results of the flow velocity distribution of a gas of the in-plane of a wafer. This figure illustrates the results of comparison of the flow velocity of the gas on the straight line from the 6 o'clock direction to the 12 o'clock direction of the in-plane distribution in FIG. 5 for the wafer W₁ of level X1, the wafers W₁ and W₂ of level X2, and the wafer W₁ of level X3. In FIG. 7, the horizontal axis represents the position [mm] and the vertical axis represents the gas flow velocity [m/s]. As for the position, −150 mm is the outer end of the wafer W in the 6 o'clock direction, 0 mm is the center of the wafer W, and +150 mm is the outer end of the wafer W in the 12 o'clock direction.

As illustrated in FIGS. 5 to 7, at level X1, since a gas is supplied to all the wafers W₁ to W₃ in the same environment, the flow velocity distributions of the gas on all the wafers W₁ to W₃ are the same. At level X2, since the flow rate of the gas supplied to a space above the wafer W₁ and a space between the wafer W₂ and the wafer W₃ is doubled with respect to level X1, the flow velocity of the gas on the wafer W₁ and the wafer W₃ is high, whereas the flow velocity of the gas on the wafer W₂ is low. In this way, at level X2, the gas flow velocity varies between the wafers W. At level X3, the flow velocity distributions of the gas on all the wafers W₁ to W₃ are the same, and the gas is supplied on the wafers W₁ to W₃ at a flow velocity higher than that at level X1.

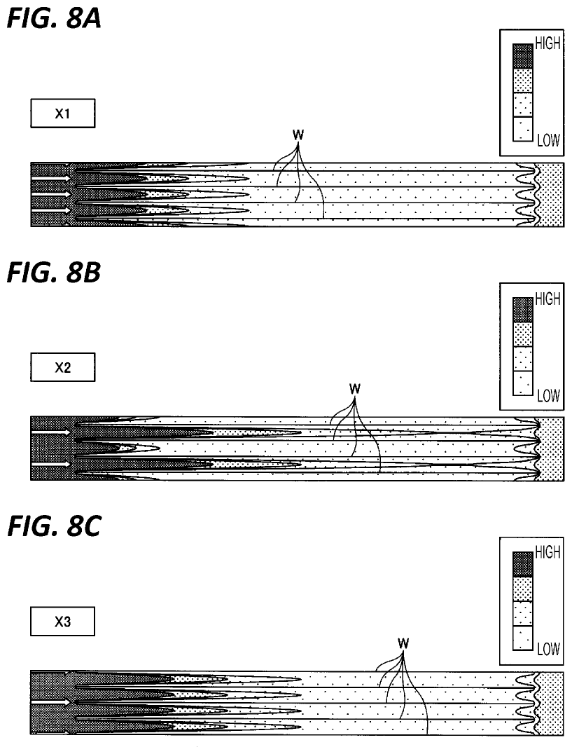

FIGS. 8A to 8C are diagrams illustrating analysis results of the flow velocity distribution of a gas between wafers. FIGS. 8A to 8C illustrate the gas flow velocity distribution obtained by analysis in a longitudinal section. FIG. 8A illustrates the result of level X1, FIG. 8B illustrates the result of level X2, and FIG. 8C illustrates the result of level X3. In FIGS. 8A to 8C, the left end is a position where the gas nozzle 34 is arranged, and the right end is a position where the exhaust slit 15 is arranged. Further, in FIGS. 8A to 8C, the ejection direction of the gas is indicated by an arrow.

As illustrated in FIGS. 8A and 8C, it can be seen that at level X3, a region where the gas flow velocity is higher than that at level X1 extends to the central portion of the wafer W. From this result, by thinning out the number of gas holes 34a to half the number of wafers W and arranging each of the gas holes 34a at the same height position as the wafer W, it is considered that the variation in the gas flow velocity between the central portion and the end portion of the wafer W can be reduced, thereby improving the in-plane uniformity of the gas flow velocity.

Further, as illustrated in FIG. 8B, at level X2, a large difference in the flow velocity of the gas at the central portion of the wafer W occurs between a space between wafers W including the height position at which the gas holes 34a are arranged and a space between wafers W adjacent to the upper and lower sides of the space between wafers W including the height position. This is because the gas holes 34a are set to be located in the middle between the wafers W adjacent to each other in the vertical direction, so that the gas ejected from the gas holes 34a directly enters the space between wafers W. As a result, the influence of the presence or absence of the gas holes 34a is large. Meanwhile, at level X3, since the gas holes 34a are arranged at the same height as the wafer W, the gas ejected from the gas holes 34a collides with the side surface of the wafer W to become a flow which is separated into spaces between wafers W above and below the wafer W. As a result, even if the number of gas holes 34a is thinned out to half the number of wafers W, the influence of the presence or absence of gas holes 34a is small. Further, at level X3, since the number of gas holes 34a is half that of level X1, the flow velocity of the gas ejected from each of the gas holes 34a is high. Therefore, at level X3, the gas flow velocity in the central portion of the wafer W is higher than that at level X1. From this result, by thinning out the number of gas holes 34a to half and arranging each of the gas holes 34a at the same height position as the wafer W, it is considered that the in-plane uniformity and the inter-plane uniformity of the gas flow velocity can be improved.

Next, in the processing apparatus 1 illustrated in FIGS. 1 and 2, a simulation by thermo-fluid analysis is conducted on the concentration distribution of reactive species on the wafer W when a gas is ejected from the gas holes 34a of the gas nozzle 34 into the inner tube 11. The reason why the concentration distribution of the reactive species is analyzed is that the film thickness of a predetermined film formed on the wafer W is due to the concentration of the reactive species produced by thermal decomposition of a precursor gas. In this simulation, two levels in which the arrangement of the gas holes 34a is changed, that is, level X2 (see FIG. 4B) and level X3 (see FIG. 4C), were analyzed.

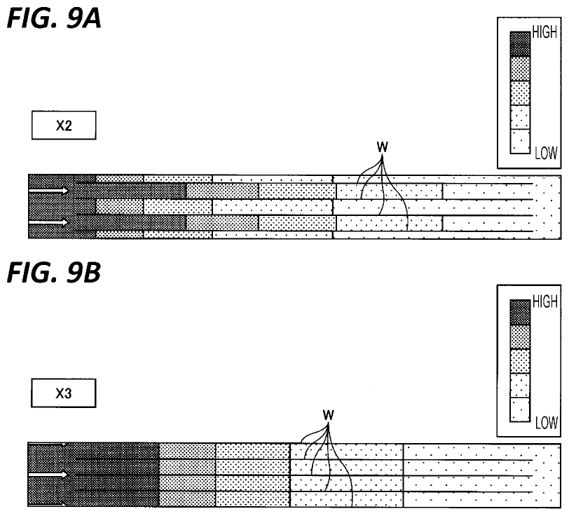

FIGS. 9A and 9B are diagrams illustrating analysis results of the active species concentration distribution between wafers. FIGS. 9A and 9B illustrate the active species concentration distribution obtained by analysis in a longitudinal section. FIG. 9A illustrates the result of level X2, and FIG. 9B illustrates the result of level X3. In FIGS. 9A and 9B, the left end is a position where the gas nozzle 34 is arranged, and the right end is a position where the exhaust slit 15 is arranged. Further, in FIGS. 9A and 9B, the ejection direction of a gas is indicated by an arrow.

As illustrated in FIG. 9A, at level X2, the concentration distribution of reactive species is very different between a space between the wafers W including the height position at which the gas holes 34a are arranged and a space between the wafers W adjacent to the upper and lower sides of the space between the wafers W including the height position. Meanwhile, as illustrated in FIG. 9B, at level X3, the concentration distributions of reactive species are substantially the same on all the wafers W. From this result, by thinning out the number of gas holes 34a to half and arranging each of the gas holes 34a at the same height position as the wafer W, it is considered that the inter-plane uniformity of the concentration of reactive species on the wafer W can be improved.

In the above-described embodiment, the case where the plurality of gas holes 34a provided in one gas nozzle 34 are arranged in every other tier of the plurality of wafers W accommodated in multiple tiers has been described, but the present disclosure is not limited thereto. For example, any one of the plurality of gas holes provided in the plurality of gas nozzles may be arranged in every other tier of the plurality of wafers W accommodated in multiple tiers. This makes it possible to suppress an increase in the internal pressure of the gas nozzle. As a result, it is possible to prevent the precursor gas from being excessively decomposed inside the gas nozzle and depositing a film. Further, by using a plurality of gas nozzles, since the number of gas holes per one gas nozzle can be reduced, the variation in the gas flow rate in the longitudinal direction of the gas nozzles is small.

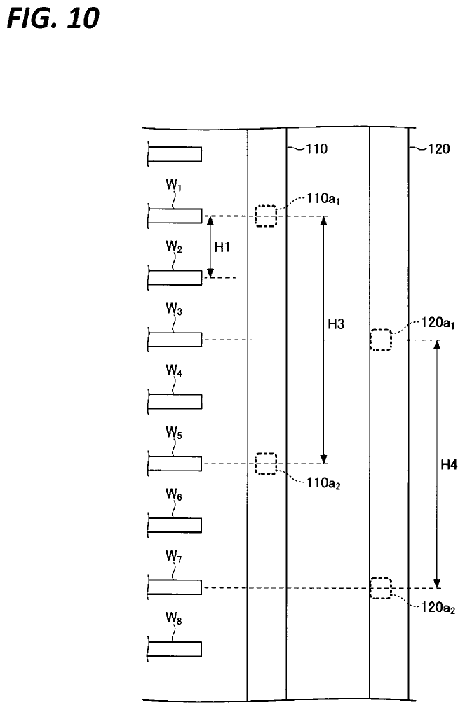

FIG. 10 is a diagram illustrating another example of the positional relationship between the gas holes and the wafers. In the example illustrated in FIG. 10, any one of a plurality of gas holes 110a and 120a provided in two gas nozzles 110 and 120 is arranged in every other tier of a plurality of wafers W accommodated in multiple tiers. That is, the plurality of gas holes 110a are arranged so that the pitch H3 between adjacent gas holes 110a is four times the pitch H1 between adjacent wafers W. Further, the plurality of gas holes 120a are arranged so that the pitch H4 between adjacent gas holes 120a is four times the pitch H1 between the adjacent wafers W. Specifically, a gas hole 110a₁ is arranged at the same height as the wafer W₁ and faces the side surface of the wafer W₁. As a result, the gas hole 110a₁ ejects a gas toward the side surface of the wafer W₁. The gas hole 120a₁ is arranged at the same height as the wafer W₃ and faces the side surface of the wafer W₃. As a result, the gas hole 120a₁ ejects the gas toward the side surface of the wafer W₃. The gas hole 110a₂ is arranged at the same height as the wafer W₅ and faces the side surface of the wafer W. As a result, the gas hole 110a₂ ejects the gas toward the side surface of the wafer W₅. The gas holes 120a₂ is arranged at the same height as the wafer W₇ and faces the side surface of the wafer W₇. As a result, the gas hole 120a₂ ejects the gas toward the side surface of the wafer W₇.

In the above-described embodiment, descriptions have been made on the case where the gas nozzle is an L-shaped pipe, but the present disclosure is not limited thereto. For example, the gas nozzle may be a straight pipe that extends inside the side wall of the inner tube along the longitudinal direction of the inner tube and has its lower end inserted in and supported by a nozzle support (not illustrated).

In the above-described embodiment, descriptions have been made on the case where the processing apparatus is an apparatus that supplies a gas from the gas nozzles arranged along the longitudinal direction of the processing container and exhausts the gas from the exhaust slit arranged opposite to the gas nozzles, but the present disclosure is not limited thereto. For example, the processing apparatus may be an apparatus that supplies a gas from the gas nozzles arranged along the longitudinal direction of the boat and exhausts the gas from the gas outlet arranged above or below the boat.

In the above-described embodiment, descriptions have been made on the case where the processing container is a container having a double-tube structure having the inner tube and the outer tube, but the present disclosure is not limited thereto. For example, the processing container may be a container having a single-tube structure.

In the above-described embodiment, descriptions have been made on the case where the processing apparatus is a non-plasma apparatus, but the present disclosure is not limited thereto. For example, the processing apparatus may be a plasma apparatus such as a capacitively-coupled plasma apparatus or an inductively-coupled plasma apparatus.

According to the present disclosure, it is possible to improve the in-plane uniformity and inter-plane uniformity of film thickness.

From the foregoing, it will be appreciated that various exemplary embodiments of the present disclosure have been described herein for purposes of illustration, and that various modifications may be made without departing from the scope and spirit of the present disclosure. Accordingly, the various exemplary embodiments disclosed herein are not intended to be limiting, with the true scope and spirit being indicated by the following claims.

What is claimed is:

1. A processing apparatus comprising:
a processing container having a substantially cylindrical shape and configured to accommodate a plurality of substrates in multiple tiers at intervals in a longitudinal direction of the processing container; and
a gas nozzle extending in the longitudinal direction of the processing container and having a plurality of gas holes provided at intervals in a longitudinal direction of the gas nozzle to eject a gas into the processing container,
wherein the plurality of gas holes are arranged every other tier of the plurality of substrates accommodated in multiple tiers, and
the plurality of gas holes eject the gas toward side surfaces of corresponding substrates.

2. The processing apparatus according to claim 1, wherein the plurality of gas holes are oriented toward a center of the processing container.

3. The processing apparatus according to claim 2, wherein the plurality of gas holes are arranged at a same height as the corresponding substrates.

4. The processing apparatus according to claim 3, wherein an exhaust slit is provided in the processing container facing the plurality of gas holes to exhaust the gas in the processing container.

5. The processing apparatus according to claim 1, wherein the plurality of gas holes are arranged at a same height as the corresponding substrates.

6. The processing apparatus according to claim 1, wherein an exhaust slit is provided in the processing container facing the plurality of gas holes to exhaust the gas in the processing container.

7. A processing apparatus comprising:
a processing container having a substantially cylindrical shape and configured to accommodate a plurality of substrates in multiple tiers at intervals in a longitudinal direction of the processing container; and
a plurality of gas nozzles extending in the longitudinal direction of the processing container, and each having a plurality of gas holes provided at intervals in a longitudinal direction of the gas nozzle to eject the gas into the processing container,
wherein any one of the plurality of gas holes provided in the plurality of gas nozzles is arranged every other tier of the plurality of substrates accommodated in multiple tiers, and
the plurality of gas holes eject the gas toward side surfaces of corresponding substrates.
